(19) United States
(12) Patent Application Publication
(10) Pub. No.: US 2024/0427390 A1
(43) Pub. Date: Dec. 26, 2024

(54) PROCESSOR UNIT WITH ACTIVE COOLING SYSTEM FOR PROCESSOR DEVICE

(71) Applicant: Raytheon Company, Waltham, MA (US)

(72) Inventors: Christopher M. Cosner, Manhattan Beach, CA (US); Carlos Peralta, Rancho Palos Verdes, CA (US)

(73) Assignee: Raytheon Company, Waltham, MA (US)

(21) Appl. No.: 18/339,984

(22) Filed: Jun. 22, 2023

(51) Int. Cl. G06F 1/20; B64G 1/50; H05K 1/02; H05K 7/20

(52) U.S. Cl. CPC G06F 1/206; H05K 1/0201; H05K 7/20263; H05K 7/20272; H05K 7/20281; H05K 7/20445; H05K 7/205; B64G 1/503

(57) ABSTRACT

A processor unit includes a cooling unit for dedicated cooling of a processor device that includes at least one processor. The cooling unit includes a pumped liquid loop that circulates a working fluid to remove heat from the processor device, and to transmit that heat to a passive radiator thermally coupled to the liquid loop, to radiate the heat to an external environment. The cooling unit may be used in conjunction with additional cooling of a board, such as a printed wiring board, to which the processor device is operatively and thermally coupled. The cooling unit may be part of a spacecraft, and may enable use of high-powered processing devices as part of such spacecraft.

### FIELD

The disclosure is in the field of cooling units for processor devices.

### BACKGROUND

High-powered processors present cooling challenges for flight vehicles, such as space vehicles, due to the unavailability (or difficulty) of forced air cooling, and due to mass constraints.

### SUMMARY

A processor unit includes a computing processor device that is actively cooled by a pumped liquid loop, which in turn transfers heat to a passive radiator, which transfer heat to an external environment by thermal radiative cooling.

The active cooling may be combined with passive cooling of a wiring board to which the processor device is coupled. The passive cooling of the wiring board may include an additional passive radiator that transfers heat to the external environment by thermal radiation.

Combined cooling of a dedicated pumped liquid cooling loop for a processor device, and separate cooling of a wiring board, each coupled to respective separate passive radiators, enables spacecraft (or other flight vehicles) use of high-power processing devices, such as graphics processing units (GPUs) or system-on-a-chip devices (SoCs).

According to an aspect of the disclosure, a processor unit includes: a processor device, which includes at least one processor; and an active cooling unit for cooling the processor device, wherein the cooling unit includes: a liquid loop that includes a pump for circulating a working fluid for cooling the processor device; and a passive radiator, or radiator zone, coupled to the pumped liquid loop, to radiate to an external environment heat generated by the processor device, and transferred to the working fluid of the pumped liquid loop.

According to an embodiment of any paragraph of this summary, the system further includes detachable coupling features to allow the external liquid cooling loop to extend outside of the processing unit's chassis.

According to an embodiment of any paragraph(s) of this summary, the processor unit further includes a thermostatic controller operatively coupled to the pump, to control operation of the pump.

According to an embodiment of any paragraph(s) of this summary, the thermostatic controller receives input from one or more temperature sensors in the processor device.

According to an embodiment of any paragraph(s) of this summary, the thermostatic controller receives input in the form of commanded temperature setpoints from the spacecraft bus.

According to an embodiment of any paragraph(s) of this summary, the thermostatic controller receives input commands from either an autonomous on-board processor, or from a ground controller.

According to an embodiment of any paragraph(s) of this summary, the cooling loop includes a heat exchanger that is thermally coupled to the passive radiator.

According to an embodiment of any paragraph(s) of this summary, the cooling loop includes a heater exchanger that is thermally coupled to the processor device.

According to an embodiment of any paragraph(s) of this summary, the processor unit further includes thermal interface material between the heat exchanger and the passive radiator, thermally coupling the heat exchanger to the passive radiator.

According to an embodiment of any paragraph(s) of this summary, the heat exchanger includes channels through which the working fluid flows.

According to an embodiment of any paragraph(s) of this summary, the processor unit further includes a processor device cold plate thermally coupled to both the liquid loop and the processor device.

According to an embodiment of any paragraph(s) of this summary, the processor unit further includes respective layers of thermal interface material between the processor device cold plate and the liquid loop, and between the processor device cold plate and the processor device.

According to an embodiment of any paragraph(s) of this summary, the processor unit further includes: a wiring board coupled to the processor device; and a board cold plate thermally coupled to the wiring board.

According to an embodiment of any paragraph(s) of this summary, the processor unit further includes a device-board thermal interface material between the processor device and the wiring board.

According to an embodiment of any paragraph(s) of this summary, the board cold plate is thermally coupled to an additional passive radiator, or an additional zone of the passive radiator.

According to an embodiment of any paragraph(s) of this summary, the processor unit is part of a vehicle.

According to an embodiment of any paragraph(s) of this summary, the processor unit is part of a spacecraft.

According to an embodiment of any paragraph(s) of this summary, the radiator(s) radiate heat to deep space.

According to an embodiment of any paragraph(s) of this summary, the processor device includes a CPU.

According to an embodiment of any paragraph(s) of this summary, the processor device includes a GPU.

According to an embodiment of any paragraph(s) of this summary, the processor device uses at least 50 Watts of power.

According to an embodiment of any paragraph(s) of this summary, the processor device consumes from 50 Watts to 2000 Watts of power.

According to an embodiment of any paragraph(s) of this summary, the working fluid is ammonia.

According to an embodiment of any paragraph(s) of this summary, the working fluid includes glycol.

According to an embodiment of any paragraph(s) of this summary, the working fluid includes water.

According to an embodiment of any paragraph(s) of this summary, the liquid loop includes a liquid reservoir.

According to an embodiment of any paragraph(s) of this summary, the cold plate includes one or more of aluminum, copper, beryllium, or a beryllium and aluminum metal matrix composite material, such as that sold under the trademark AlBeMet.

According to an embodiment of any paragraph(s) of this summary, the thermal interface includes thermally conductive material in epoxy.

According to an embodiment of any paragraph(s) of this summary, the thermal interface includes thermally conductive material in room-temperature-vulcanizing silicone.

According to an embodiment of any paragraph(s) of this summary, the processor device is a system-on-a-chip processor.

According to an embodiment of any paragraph(s) of this summary, the processor device has but single processor.

According to an embodiment of any paragraph(s) of this summary, the platform dimensions of the processor device are less than 50 mm×50 mm (2″×2″) in area.

According to an embodiment of any paragraph(s) of this summary, the cooling loop includes a fill/drain valve.

According to an aspect of the disclosure, a method of cooling a processor device that includes at least one processor, includes the steps of: thermally coupling a cooling unit to the processor device, wherein the cooling unit includes a liquid loop that includes a pump for circulating a working fluid for cooling the processor device; and expelling heat from the cooling loop with a passive radiator coupled to the pumped liquid system, to radiate the heat generated by the processor device to an external environment.

According to an embodiment of any paragraph(s) of this summary, the processor device is operatively coupled to a wiring board; and the method further includes cooling the wiring board by conducting heat from the wiring board through a cold plate to an additional passive radiator or an additional radiator zone.

While a number of features are described herein with respect to embodiments of the disclosure; features described with respect to a given embodiment also may be employed in connection with other embodiments. The following description and the annexed drawings set forth certain illustrative embodiments of the disclosure. These embodiments are indicative, however, of but a few of the various ways in which the principles of the disclosure may be employed. Other objects, advantages, and novel features according to aspects of the disclosure will become apparent from the following detailed description when considered in conjunction with the drawings.

### BRIEF DESCRIPTION OF THE DRAWINGS

The annexed drawings, which are not necessarily to scale, show various aspects of the disclosure.

FIG. 1 is a schematic diagram of a processor unit according to an embodiment.

FIG. 2 is a graph of radiator size versus processor device power, for a first embodiment of the system of FIG. 1 where Q₂=25 W.

FIG. 3 is a graph of pump flow versus processor device power, for the first embodiment of the system of FIG. 1 where Q₂=25 W.

FIG. 4 is a graph of radiator size versus processor device power, for a second embodiment of the system of FIG. 1. where Q₂=200 W.

FIG. 5 is a graph of pump flow versus processor device power, for the second embodiment of the system of FIG. 1 where Q₂=200 W.

FIG. 6 is a schematic diagram of a processor unit, illustrating the calculations of FIGS. 2-5.

### DETAILED DESCRIPTION

A processor unit includes a cooling unit for dedicated cooling of a processor device that includes at least one processor. The cooling unit includes a pumped liquid loop that circulates a working fluid to remove heat from the processor device, and to transmit that heat to a passive radiator thermally coupled to the liquid loop, to radiate the heat to an external environment. The cooling unit may be used in conjunction with additional cooling of a board, such as a printed wiring board, to which the processor device is operatively and thermally coupled. The cooling unit may be part of a spacecraft, and may enable use of high-powered processing devices as part of such spacecraft.

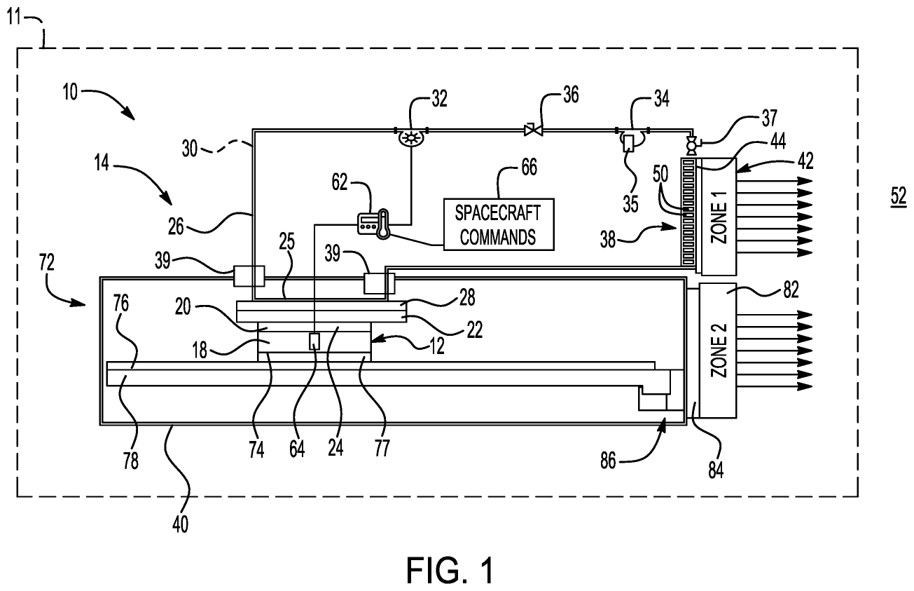

FIG. 1 shows a processor unit 10, which may be part of a vehicle 11, such as a spacecraft. The processor unit 10 includes a processor device 12, and a first cooling unit 14 for dedicated cooling of the processor device 12. The processor device 12 includes at least one processor 18. The processor device 12 may include a single processor 18, and/or may be an encapsulated and/or componentized single device.

The processor device 12 is thermally coupled at a top surface 20 of the device 12, to a processor device cold plate 22, by a thermal interface 24. The processor device cold plate 22 is also thermally coupled to a pipe segment 25 of a cooling loop 26, by a thermal interface 28.

The cooling loop 26 is a pumped recirculating liquid cooling loop, for recirculating a working fluid 30. The cooling loop 26 includes a pump 32, a reservoir 34 having a pressure transducer 35, a fill/drain valve 36, a relief valve 37, and a heat exchanger 38. The pump 32 is used to pump the working fluid around the loop 26. The reservoir 34 provides a reserve of working fluid to keep the cooling loop 26 filled with working fluid and ullage to keep it sufficiently pressurized. The fill/drain valve 36 is used to add liquid to the cooling loop 26, and/or to remove liquid from the cooling loop 26. The relief valve 37 prevents overpressurization of the cooling loop 26.

The presence of detachable liquid line couplers 39 allow the processing unit 10 to be electrically integrated within a unit chassis 40 and tested for electrical functionality prior to integrating the external cooling loop 26. Subsequently the liquid loop cooling system is attached at the couplers 39, the fluid is loaded at fill and drain valve 36, and the fully integrated assembly is tested thermally. The completed assembly is integrated with the spacecraft radiator(s) (described further below), and launched in this configuration.

The heat exchanger 38 is thermally coupled to a passive radiator 42 for removing heat from the cooling loop 26. A thermal interface 44 is in contact with both the heat exchanger 38 and the passive radiator 42, to transfer heat from the heat exchanger 38 to the passive radiator 42.

Heat generated by the processor device 12 passes through the thermal interface device 24 to the processor device cold plate 22. The cooling loop pipe segment 25 receives heat from the cold plate 22 through the thermal interface 28. The tubing of segment 25 may take a serpentine route on or may be arranged with channels or fins as in a heat exchanger, to facilitate heat transfer from the cold plate 22 to the liquid of the cooling loop 26.

The pumped flow of liquid through the cooling loop 26 carries the liquid heated at the serpentine pipe segment (or device heat exchanger) 25 to the heat exchanger 38. The heat exchanger 38 may be a metal block with one or more channels 50 therein. The channel(s) 50 have any suitable shape(s) for spreading heat through the heat exchanger 38 consistent with the choice of working fluid.

The heat exchanger 38 passes heat through the thermal interface 44 to the passive radiator 42. The passive radiator 42 is a structure that uses primarily radiation (as opposed to forced or natural (passive) convection, or conduction) as its heat transfer mechanism to transfer heat to the external environment 52 around the processor unit 10, such as external to the device or vehicle, such as a spacecraft or other vehicle of which the processor unit 10 is a part. The radiator 42 may be a suitable panel of thermally-conductive material, for example. When on the exterior of a spacecraft such a panel radiates energy to the deep space to which it is exposed.

The operation of the pump 32 may controlled by a controller 62, which may be a thermostatic controller. The controller 62 may receive input from one or more temperature sensors 64 that sense temperature at one or more locations in the processor device 12, and/or from the pressure transducer 35 that senses pressure in the reservoir 34, to give non-limiting examples of input possibilities. The processor device 12 may have a size of 25 mm (1 inch)×25 mm (1 inch) or larger, such as 38 mm (1.5 inches)×38 mm (1.5 inches) or 50 mm (2 inches)×50 mm (2 inches), so it may be advantageous to be able to detect temperature at multiple locations within the processor device 12. The controller 62 uses this temperature input to control pump operation, for example whether to turn on the pump 32 to circulate working fluid through the loop 26, and/or at what speed to operate the pump 32.

This thermostatic controller is able to accept commands 66 from the vehicle either via autonomous on-board commanding or by ground command. For example, the controller 62 may receive input, such as commands, from higher level control in the vehicle. As a specific example, the controller 62 may be instructed to increase or decrease the speed of the pump 32 based on parameters such as the temperature within the vehicle, position of the vehicle relative to nearby radiative objects (i.e., Sun, Earth, Moon, etc.), or the planned future operation of the vehicle. Other parameters may include temperature at the radiator 42, pressure at the reservoir 35, current draw of the processing device (GPU) 28 or the board 76 and/or the temperature of the working fluid 30.

In addition to the first cooling unit 14 for cooling the top or distal surface 20 of the processor device 12, the processor unit 10 includes a second cooling unit 72. the second cooling unit 64 cools the processor device 12 from an opposite side to that of the first cooling unit 14. This opposite side is the opposite side from the top surface 20 where the first cooling surface 14 removes heat from the processor device 12. Thus the second cooling unit 72 removes heat from a bottom or proximal side (surface) 74 of the processor device 12, where the processor device 12 interfaces with a board 76, which may be a printed wiring board (PWB), a printed circuit board (PCB), or other device for making electrical connections with the processor device. There may be a thermal interface 77 between the processor device 12 and the board 76, that facilitates heat transfer.

The second cooling unit 64 includes a cold plate 78 that is thermally coupled to the board 76, either directly in contact with the board 76, or in contact with the board 76 through a thermal interface. The cold plate 78 receives heat from the processor device 12 and the board 76, and transports the heat to a passive radiator 82, through an intervening thermal interface 84. There may be a locking mechanism 86, such as including a wedge lock, to secure the cold plate 78 in place.

The heat transfer from the processor device 12 to the passive radiator 82 may be conductive heat transfer, through the intervening thermal interface 77, the board 76, the cold plate 78, and the thermal interface 84. The passive radiator 82 employs radiative heat transfer, such as to deep space, to transfer the waste heat to the external environment 52. The passive radiator 82 may be a panel or other suitable structure, and may be similar to the passive radiator 42. The radiators 42 and 82 may be separate zones or regions of a single radiator structure.

The processor device 12 may thus be cooled by both of the cooling units 14 and 72, which draw heat from opposite sides of the processor device 12. This allows for effective cooling even when the processor device 12 produces a large amount of heat. In particular, the pumped-liquid cooling of the first cooling unit 14 provides dedicated cooling for the processor device 12, without as much thermal resistance as present in the second cooling unit 64, because of the multiplicity of thermal interfaces in the second cooling unit.

The cold plates 22 and 78 may be made of suitable thermally-conductive material. Examples of suitable materials include aluminum (e.g., Al-6061), copper (e.g., Cu 110), beryllium (Be), and a beryllium and aluminum metal matrix composite material, such as that sold under the trademark AlBeMet.

The various thermal interfaces may be suitable materials, such as epoxy or room-temperature-vulcanizing (RTV) silicone, impregnated with thermally conductive materials, such as with silver particles. Such materials provide good contact between surfaces to be thermally coupled together, with some compliance to fill gaps, along with good thermal conductivity.

The recirculating working fluid 30 for the cooling loop 26 may be any of a variety of suitable liquids. It is desirable that the working fluid have boiling and freezing points that are outside the range of temperature for which the cooling loop 26 is to be operated. Examples of suitable liquids include ammonia, glycol, and glycol-water mixtures. The working fluid may be selected to endure low temperatures, for example being able to endure temperatures down to −55° C. (or lower) without freezing.

The system 10 may be configured to operate in a temperature range of −15° C. to 50° C. Many other operating temperature ranges are possible.

The processor device 12 may be or may include a processor such as a central processing unit (CPU) or a graphics processing unit (GPU). A GPU is a processor that is made up of many smaller and more specialized cores. By working together, the cores deliver massive performance when a processing task can be divided up and processed across many cores The processor device 12 may be a system-on-a-chip (SoC) integrated circuit, for example that integrates a microcontroller, microprocessor, or perhaps several processor cores with peripherals like a GPU, all as part of a single encapsulated or distinct device. Such processor devices are meant to cover single-core processors, as well as multicore processors such as dual-core processors and quad-core processors. By processor device it is intended the device be a discrete device, with any internal connections between its components being integral parts of the device, as opposed to (for example) being separate conductive traces, or on separate boards.

The processor device 12 may consume at least 50 Watts of power. More narrowly, the processor device 12 may consume from 50 Watts to 2000 Watts of power.

The use of zoned radiators, the separate cooling units 14 and 72, with their respective radiators 42 and 82, allows differential control of temperatures of the processing device 12 and the board 76. The commandable setpoint of the controller 62 enables a realized temperature for the processor device 12 that is independently controllable from the temperature of other parts of the system.

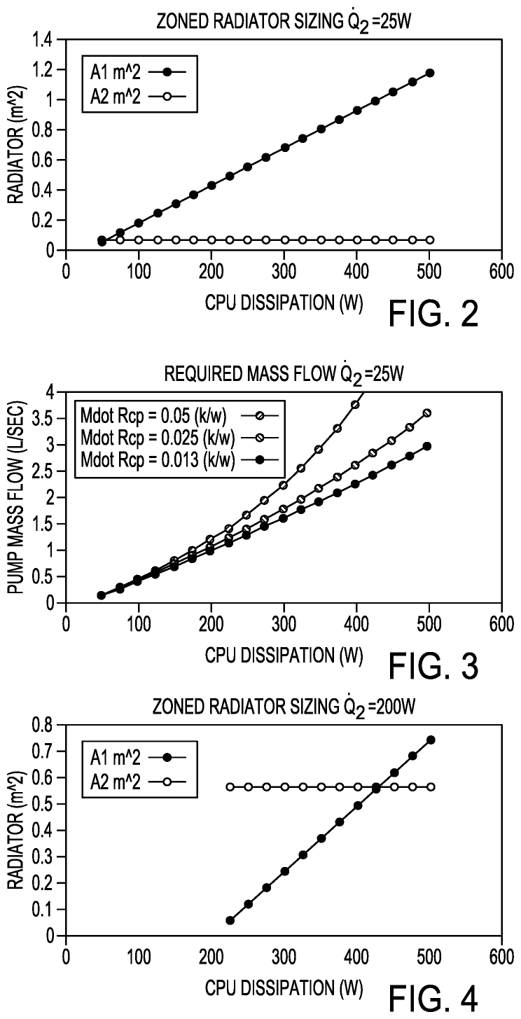

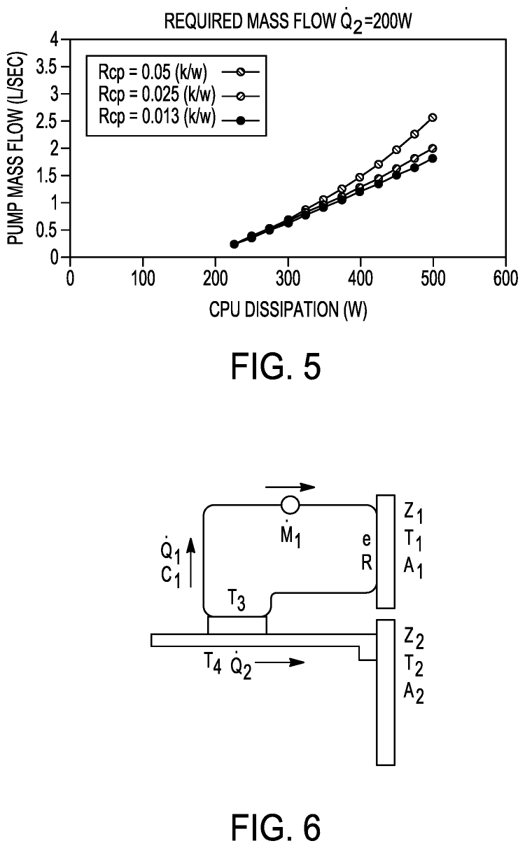

By use of the zoned radiators, the thermally separate radiators 42 and 82 (which may be parts of a single radiator structure), substantial reductions in radiator area and/or thermal cycling of components may be achieved. With regard to the sizing of the radiators, FIGS. 2-5 show graphs regarding sizing of radiators and the pump mass flow versus the power consumed by the processor device 12 for two specific examples, one in which the heat load to be dissipated by the second radiator 82 is 25 W (FIGS. 2 and 3), and one in which the heat load to be dissipated by the second radiator 82 is 200 W (FIGS. 4 and 5).

The graphs in FIGS. 2-5 illustrate the effect of parameters on the component sizing and operating factors of the separate cooling units 14 and 72. Such information can be useful, for instance, in configuring the controller 62 to optimize operation of the cooling unit 14 based on minimizing power, on reducing thermal cycling, or to achieve other goals.

The processor unit 10 may be part of a spacecraft. The cooling of the processor unit advantageously combines a liquid loop with a radiator relying on radiative heat transfer. The combination enables the use of high-heat-producing specific electronic components in a space-based system. The multiple cooling units provides for radiating the processor device's heat independently from that of the overall system that the processor device is a part of.

The closed-loop system 14 for cooling the processor device 12 provides advantages over prior systems. Among these advantages are the potential for increase in reliability and durability for both the processor device 12 and the pump 32, reduced thermal cycling, reduced radiator size and mass relative to fully passive cooling units, and active control that can enable change of the thermostat's setpoint and/or the mass flow rate of the pump 32. Optimal control of the thermostat's setpoint via either autonomous on-board commanding or ground-user in the loop real-time commanding will reduce mass, size, power, and cost of the overall space-vehicle design. ‘Outer loop’ control based on a state vector including temperatures, pressures and current draw can be designed based on optimal control techniques well known to those practiced in the art of Autonomous Control System design.

The combination of the active cooling (convection of the liquid loop) of the first cooling unit 14 and the passive cooling (heat conduction) of the second cooling unit 72 provides a more efficient and effective way of cooling a heat-producing processor device 12 that is part of an electronic layout that produces additional heat. The ability to provide directed, controllable cooling to the processor device 12 may enable use of high-heat devices in situations, such as in spacecraft, where they have not previously been practically employable.

With reference now to FIG. 6, the following method can be used to size the cooling system. Consider the total heat-flux from the processor device 12 to be:

$${\dot{Q}}_{TOTAL} = {\dot{Q}}_{1} + {\dot{Q}}_{2} \qquad ( 1 )$$

where \dot{Q}_{TOTAL} is the total heat heat transferred to the radiators (or radiator zones), and \dot{Q}₁ and \dot{Q}₂ are the heat loss of the respective radiators (or radiator zones) 42 and 82.

Then the expressions relating the radiators (or radiator zones) 42 and 82 to the desired temperatures are:

$${\dot{Q}}_{1} = {A}_{1} εσ {T}_{1}^{4} \qquad ( 2 )$$

$${\dot{Q}}_{2} = {A}_{2} εσ {T}_{2}^{4} \qquad ( 3 )$$

where A indicates area of a radiator (or radiator zone), E indicates emissivity, σ indicates Boltzmann's constant, and T indicates temperature of a radiator (or radiator zone).

The expression for the mass flow rate \dot{m} required from the pump is given by:

$$\dot{m} = \frac{1}{{C}_{1}} ( \frac{1}{e} - 1 ) / ( \frac{{T}_{3} - {T}_{1}}{{\dot{Q}}_{1}} - R ) \qquad ( 4 )$$

where C₁ is the specific heat of the working fluid 30, e is the efficiency of the heat exchanger, T₃ is the desired processor core device temperature, and R is the thermal resistance at the thermal interfaces 24 and 28.

Although the disclosure has been shown and described with respect to a certain embodiment or embodiments, equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the disclosure. In addition, while a particular feature of the disclosure may have been described above with respect to only one or more of several illustrated embodiments, such feature may be combined with one or more other features of the other embodiments, as may be desired and advantageous for any given or particular application.

1. A processor unit, the system comprising:
a processor device, which includes at least one processor; and
a cooling unit for cooling the processor device, wherein the cooling unit includes: a liquid loop that includes a pump for circulating a working fluid for cooling the processor device; and
a passive radiator coupled to the pumped liquid system, to radiate to an external environment heat generated by the processor device, and transferred to the working fluid of the pumped liquid system.

2. The processor unit of claim 1, further comprising a thermostatic controller operatively coupled to the pump, to control operation of the pump.

3. The processor unit of claim 2, wherein the thermostatic controller receives input from one or more temperature sensors in the processor device.

4. The processor unit of claim 2, wherein the thermostatic controller receives input commands from either an autonomous on-board processor, or from a ground controller.

5. The processor unit of claim 1, wherein the cooling loop includes a heat exchanger that is thermally coupled to the passive radiator.

6. The processor unit of claim 5, further comprising thermal interface material between the heat exchanger and the passive radiator, thermally coupling the heat exchanger to the passive radiator.

7. The processor unit of claim 5, wherein the heat exchanger includes channels through which the working fluid flows.

8. The processor unit of claim 1, further comprising a processor device cold plate thermally coupled to both the liquid loop and the processor device.

9. The processor unit of claim 8, further comprising respective layers of thermal interface material between the processor device cold plate and the liquid loop, and between the processor device cold plate and the processor device.

10. The processor unit of claim 1, further comprising:
a wiring board coupled to the processor device; and
a board cold plate thermally coupled to the wiring board.

11. The processor unit of claim 9, wherein the board cold plate is thermally coupled to an additional passive radiator.

12. The processor unit of claim 1, wherein the processor device is part of a spacecraft.

13. The processor unit of claim 12, wherein, in operation, the passive radiator radiates heat to deep space.

14. The processor unit of claim 1, wherein the processor device includes a GPU.

15. The processor unit of claim 1, wherein the processor device uses at least 100 Watts of power.

16. The processor unit of claim 1, wherein the processor device consumes from 100 Watts to 1000 Watts of power.

17. The processor unit of claim 1, wherein the working fluid is ammonia.

18. The processor unit of claim 1, wherein dimensions of processor device is less than 25 mm×25 mm (1.5″×1.5″) in area.

19. A method of cooling a processor device that includes at least one processor, the method comprising:
thermally coupling a cooling unit to the processor device, wherein the cooling unit includes a liquid loop that includes a pump for circulating a working fluid for cooling the processor device; and
expelling heat from the cooling loop with a passive radiator coupled to the pumped liquid system, to radiate the heat generated by the processor device to an external environment.

20. The method of claim 19,
wherein the processor device is operatively coupled to a wiring board; and
further comprising cooling the wiring board by conducting heat from the wiring board through a cold plate to an additional passive radiator.
